(19) United States
(12) Patent Application Publication
(10) Pub. No.: US 2021/0134683 A1
(43) Pub. Date: May 6, 2021

(54) Method of Manufacturing Semiconductor Device, Non-transitory Computer-readable Recording Medium and Substrate Processing Apparatus

(71) Applicant: Kokusai Electric Corporation, Tokyo (JP)

(72) Inventors: Osamu MORITA, Toyama (JP); Shuichi KUBO, Toyama (JP); Yuji YAMAOKA, Toyama (JP)

(21) Appl. No.: 17/037,034

(22) Filed: Sep. 29, 2020

(30) Foreign Application Priority Data
Oct. 31, 2019 (JP) 2019-198080
Aug. 31, 2020 (JP) 2020-145475

(51) Int. Cl. H01L 21/66; H01L 21/02; C23C 16/24; C23C 16/52

(52) U.S. Cl. CPC H01L 22/20; H01L 21/02381; H01L 21/02532; C23C 16/4408; H01L 21/02634; C23C 16/24; C23C 16/52; H01L 21/0262

(57) ABSTRACT

Described herein is a technique capable of stabilizing conditions in a furnace at the start of a film-forming process. According to one aspect of the technique, there is provided a method of manufacturing a semiconductor device, including: pre-processing of preparing a process environment in a process furnace of a substrate processing apparatus; film-forming by processing a substrate; and post-processing, wherein the pre-processing comprises (a1) determining whether to execute a maintenance recipe for a target object in the substrate processing apparatus, wherein (a1) is performed first in the pre-processing.

### CROSS REFERENCE TO RELATED APPLICATIONS

This application claims foreign priority under 35 U.S.C. § 119(a)-(d) to Application No. JP 2019-198080 filed on Oct. 31, 2019, and Application No. JP 2020-145475 filed on Aug. 31, 2020, the entire contents of which are hereby incorporated by reference.

### TECHNICAL FIELD

The present disclosure relates to a method of manufacturing a semiconductor device, a non-transitory computer-readable recording medium and a substrate processing apparatus.

### BACKGROUND

In a semiconductor manufacturing apparatus serving as a substrate processing apparatus, a maintenance process may be performed before or after performing a film-forming-process. In the present specification, the maintenance process may refer to various processes such as a process of removing by-products in a furnace and a purge process of maintaining an environment in the furnace under specific conditions. Recently, in order to improve a productivity of an apparatus such as the semiconductor manufacturing apparatus (that is, in order to reduce a downtime of the apparatus), a function of automatically performing the maintenance process is widely used in the apparatus.

For example, according to some related arts, an alarm is generated and a cleaning recipe is executed when a current value of apparatus data to be monitored reaches a predetermined condition. For example, according to another related arts, an error correction process is performed in a first step (leading step) of a film-forming step even when an error occurs in a preparation step performed before the film-forming step.

However, when the current value reaches a predetermined threshold value and the maintenance process is automatically performed, a situation in the furnace at the start of the film-forming process may change.

### SUMMARY

Described herein is a technique capable of stabilizing a situation in a furnace at the start of a film-forming process.

According to one aspect of the technique of the present disclosure, there is provided a method of manufacturing a semiconductor device, including: pre-processing of preparing a process environment in a process furnace of a substrate processing apparatus; film-forming by processing a substrate; and post-processing, wherein the pre-processing includes (a1) determining whether to execute a maintenance recipe for a target object in the substrate processing apparatus, wherein (a1) is performed first in the pre-processing.

### BRIEF DESCRIPTION OF THE DRAWINGS

FIG. 1 schematically illustrates an exemplary horizontal cross-section of a substrate processing apparatus preferably used in one or more embodiments described herein.

FIG. 2 schematically illustrates an exemplary vertical cross-section of the substrate processing apparatus preferably used in the embodiments described herein.

FIG. 3 schematically illustrates an exemplary vertical cross-section of a process furnace of the substrate processing apparatus preferably used in the embodiments described herein.

FIG. 4 is a block diagram schematically illustrating a functional configuration of a controller preferably used in the embodiments described herein.

FIG. 5 schematically illustrates an example of a process flow preferably used in the embodiments described herein.

FIG. 6 schematically illustrates an example of maintenance items preferably used in the embodiments described herein.

FIG. 7 schematically illustrates an example of a maintenance process preferably used in the embodiments described herein.

FIG. 8 schematically illustrates a pre-processing in the process flow shown in FIG. 5.

FIG. 9 schematically illustrates a maintenance process determination step in the pre-processing step shown in FIG. 8.

FIG. 10A schematically illustrates a comparative example in which a film-forming process is performed a plurality of times in a single job.

FIG. 10B schematically illustrates an example of the process flow preferably used in the embodiments described herein in which the film-forming process is performed a plurality of times in a single job.

FIG. 11 schematically illustrates another example of the process flow preferably used in the embodiments described herein.

### DETAILED DESCRIPTION

Hereinafter, one or more embodiments (also simply referred to as “embodiments”) according to the technique of the present disclosure will be described with reference to the drawings.

### Embodiment

An embodiment according to the technique of the present disclosure will be described with reference to the drawings.

### Outline of Substrate Processing Apparatus

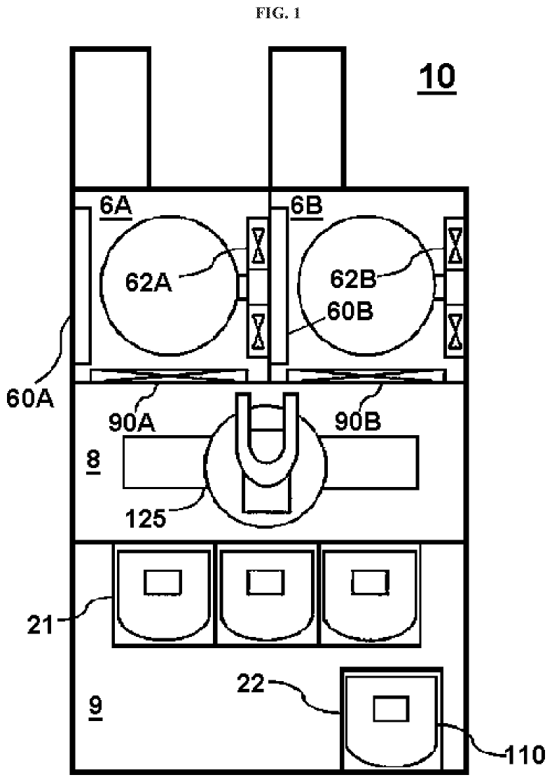

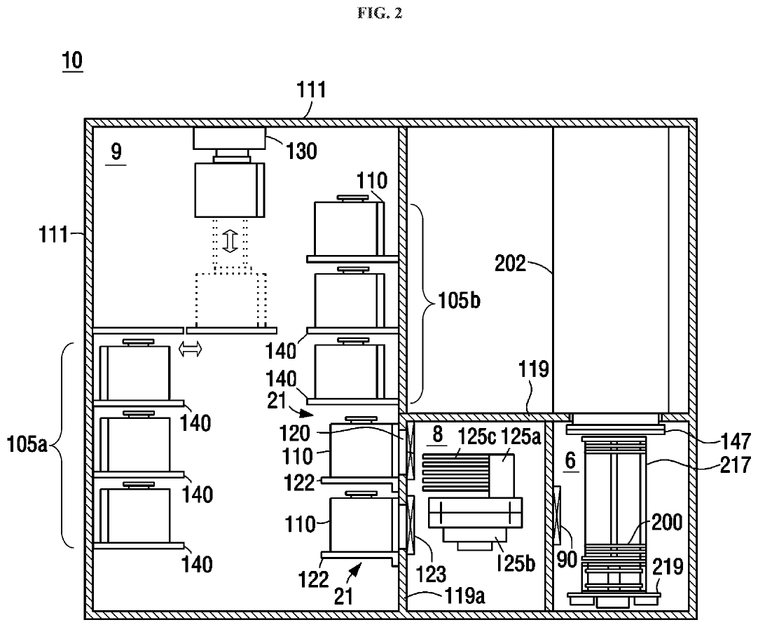

Hereinafter, the embodiment will be described with reference to FIGS. 1 and 2. For example, a substrate processing apparatus according to the present embodiment is configured as a substrate processing apparatus capable of performing a substrate processing in a method of manufacturing a semiconductor device such as an IC (integrated circuit). In the following description, the present embodiment will be described by way of an example in which a vertical type apparatus (hereinafter, also simply referred to as a “processing apparatus”) configured to perform a process such as an oxidation process, a diffusion process and a CVD (Chemical Vapor Deposition) process on a substrate is used as the substrate processing apparatus.

As shown in FIGS. 1 and 2, a substrate processing apparatus 10 according to the present embodiment includes two adjacent processing modules each serving as a process furnace 202 described later. Each of the processing modules is a vertical type processing module configured to collectively process several tens of wafers including a wafer 200 serving as a substrate. In the present specification, the term “components constituting the substrate processing apparatus 10” may refer to components such as components constituting the process furnace 202, components provided in a loading chamber 6 (that is, loading chambers 6A and 6B) and components provided in a transfer chamber 8. In addition, the term “components constituting the substrate processing apparatus 10” may also refer to the substrate processing apparatus 10 itself.

The loading chambers 6A and 6B each serving as a preparation chamber are provided below the process furnace 202. Hereinafter, the loading chamber 6A and the loading chambers 6B may be individually or collectively referred to as the loading chamber 6. The transfer chamber 8 is provided adjacent to the loading chambers 6A and 6B on front sides of the loading chambers 6A and 6B. The transfer chamber 8 is provided with a wafer transfer device 125 configured to transfer the wafer 200 serving as the substrate. According to the present embodiment, the two processing modules each serving as the process furnace 202 described later are provided above the loading chambers 6A and 6B, respectively.

A storage chamber (which is a pod transfer space) 9 configured to store a pod 110 such as a FOUP (Front Opening Unified Pod) is provided on a front side of the transfer chamber 8. The pod 110 serves as a storage container capable of storing a plurality of wafers including the wafer 200. A loading port (also referred to as a “loading port shelf”) 22 serving as a loading/unloading port is provided on an entire surface of the storage chamber 9, and the pod 110 may be transferred (loaded) into or transferred (unloaded) out of the substrate processing apparatus 10 through the loading port 22.

Gate valves 90A and 90B each serving as an isolation structure are provided at a boundary wall (adjacent surface) between the loading chamber 6 and the transfer chamber 8. Hereinafter, the gate valve 90A and the gate valve 90B may be individually or collectively referred to as a “gate valve 90”. Pressure detectors (not shown) are provided in the transfer chamber 8 and the loading chamber 6, respectively, and an inner pressure of the transfer chamber 8 may be set to be lower than an inner pressure of the loading chamber 6. In addition, oxygen concentration detectors (not shown) are provided in the transfer chamber 8 and the loading chamber 6, respectively, and oxygen concentrations in the transfer chamber 8 and the loading chamber 6 may be maintained lower than an oxygen concentration in the atmosphere. It is preferable that the oxygen concentrations in the transfer chamber 8 and the loading chamber 6 are maintained equal to or less than 30 ppm.

A clean air supply structure (not shown) configured to supply clean air is provided at a ceiling portion of the transfer chamber 8. For example, the clean air supply structure is configured to circulate an inert gas serving as the clean air in the transfer chamber 8. By circulating and purging an inside of the transfer chamber 8 with the inert gas, it is possible to maintain a clean state of an inner atmosphere of the transfer chamber 8.

According to the configurations of the components such as the clean air supply structure described above, it is possible to suppress particles and the like in the transfer chamber 8 and the loading chambers 6A and 6B from entering the process furnace 202. It is also possible to suppress a natural oxide film from being formed on the wafer 200 in the transfer chamber 8 or in the loading chambers 6A and 6B.

A plurality of pod openers including a pod opener 21 (also simply referred to as “pod openers 21”), for example, three pod openers are provided in a rear region of the storage chamber 9 on a boundary wall between the storage chamber 9 and the transfer chamber 8 as the pod openers 21. Each of the pod openers 21 is configured to open and close a cap of the pod 110. When the cap of the pod 110 is opened by the pod opener 21, the plurality of the wafers including the wafer 200 may be transferred (loaded) into or transferred (unloaded) out of the transfer chamber 8.

As shown in FIG. 2, the substrate processing apparatus 10 includes a housing 111 serving as a main housing of the substrate processing apparatus 10. The pod 110 configured to accommodate the plurality of the wafers including the wafer 200 is used in the substrate processing apparatus 10. For example, the wafer 200 is made of a material such as silicon.

A front maintenance port (not shown) serving as an opening provided for maintenance is provided at a front portion of a front wall of the housing 111. Front maintenance doors (not shown) configured to open and close the front maintenance port are provided at the front portion of the front wall of the housing 111. A pod loading/unloading port (not shown) is provided at the front wall of the housing 111 so as to communicate with an inside and an outside of the housing 111. The pod 110 may be transferred into and out of the housing 111 through the pod loading/unloading port. The pod loading/unloading port may be opened or closed by a front shutter (not shown).

The loading port 22 which is used as the loading/unloading port is provided at the pod loading/unloading port. The pod 110 is aligned while placed on the loading port 22. The pod 110 may be loaded onto or unloaded from the loading port 22 by an in-process transfer apparatus (not shown).

A plurality of pod shelves (storage shelves: also simply referred to as “pod shelves”) 105a are provided in a rear portion of the front wall of the housing 111 in a matrix shape vertically and horizontally around the pod loading/unloading port. The pod shelves 105a are provided with a plurality of placement plates (also simply referred to as “placement plates”) 140 serving as a part of a storage structure configured to place and store a plurality of pods including the pod 110 (also simply referred to as “pods 110”). The storage structure may include the placement plates 140 and a horizontal mover (not shown) which is a pod shelf horizontal mover. The horizontal mover is configured to horizontally move each of the placement plates 140 between a standby position where the pod 110 is stored and a delivery position where the pod 110 is delivered. Each of the placement plates 140 arranged on the same straight line in the horizontal direction is configured as a stage of each of the pod shelves 105a, and the pod shelves 105a are provided in the vertical direction in a multistage manner. It is possible to independently move each of the placement plates 140 in a horizontal direction without being synchronized with any other of the placement plates 140 including those adjacent thereto vertically and horizontally. A pod transfer device 130 is configured to transfer the pod 110 among the loading port 22, the pod shelves 105a and the pod openers including the pod opener 21.

A plurality of pod shelves (storage shelves: also simply referred to as “pod shelves”) 105b are provided in front of a sub-housing 119 in the housing 111 in a vertical and horizontal arrangement of a matrix shape. Similar as in the pod shelves 105a provided in the rear portion of the front wall of the housing 111, it is possible to independently move each of the placement plates 140 serving as a part of the storage structure placed at each of the pod shelves 105b in a horizontal direction without being synchronized with any other of the placement plates 140 including those adjacent thereto vertically and horizontally. Hereinafter, the pod shelves 105a and the pod shelves 105b may be individually or collectively referred to as pod shelves 105. The pod shelves 105 are configured to support the pods 110 placed thereon, respectively.

A pair of wafer loading/unloading ports 120 is provided at a front wall 119a of the sub-housing 119. The wafer 200 may be loaded into or unloaded out of the sub-housing 119 through the pair of the wafer loading/unloading ports 120. The pair of the wafer loading/unloading ports 120 is arranged vertically in two stages. That is, an upper wafer loading/unloading port and a lower wafer loading/unloading port are provided as the pair of the wafer loading/unloading ports 120. A pair of pod openers including the pod opener 21 is provided at the pair of the wafer loading/unloading ports 120, respectively. For example, an upper pod opener and a lower pod opener may be provided as the pair of the pod openers. The upper pod opener may be referred to as an “upper pod opener 21”, and the lower pod opener may be referred to as a “lower pod opener 21”. In addition, the upper pod opener and the lower pod opener may be collectively or individually referred to as the “pod opener 21”. While the present embodiment will be described by way of an example in which the upper pod opener and the lower pod opener is used as the pair of the pod openers, the present embodiment is not limited thereto. For example, instead of upper pod opener and the lower pod opener, a left pod opener and a right pod opener provided in the horizontal direction may be used as the pair of the pod openers. The pod opener 21 may include a placement table 122 where the pod 110 is placed thereon and a cap attaching/detaching structure 123 configured to attach or detach the cap of the pod 110. By detaching or attaching the cap of the pod 110 placed on the placement table 122 by the pod opener 21, a wafer entrance of the pod 110 is opened or closed.

The sub-housing 119 defines the transfer chamber 8 fluidically isolated from an installation space in which the pod transfer device 130 or the pod shelves 105 are provided. The wafer transfer device 125 is provided in a front region of the transfer chamber 8. The wafer transfer device 125 is constituted by a wafer transfer structure 125a and a wafer transfer structure elevator 125b. The wafer transfer structure 125a is configured to support the wafer 200 and rotate or move the wafer 200 horizontally. The wafer transfer structure elevator 125b is configured to elevate or lower the wafer transfer structure 125a. The wafer transfer device 125 may load (charge) or unload (discharge) the wafer 200 placed on tweezers 125c (which is a support for the wafer 200) of the wafer transfer device 125 into or out of a boat (also referred to as a “substrate retainer”) 217 serving as a placement container for the wafer 200 by consecutive operations of the wafer transfer structure 125a and the wafer transfer structure elevator 125b.

The loading chamber 6 serving as a standby region in which the boat 217 is accommodated in standby is provided at a rear region of the transfer chamber 8 through the gate valve 90. The process furnace 202 in which a process chamber 201 is defined is provided above the loading chamber 6. A lower end opening of the process furnace 202 is opened and closed by a furnace opening shutter 147.

The boat 217 is elevated or lowered by a boat elevator 115 in order to load the boat 217 into the process furnace 202 or to unload the boat 217 out of the process furnace 202. A seal cap 219 serving as a lid is provided horizontally at an arm (not shown) serving as a connector connected to an elevating table of the boat elevator 115. The seal cap 219 is configured to support the boat 217 vertically and to close the lower end of opening of the process furnace 202. The boat 217 includes a plurality of supports (not shown). The plurality of the supports of the boat 217 are configured to support the plurality of the wafers including the wafer 200 in a horizontal orientation with their centers aligned concentrically in the vertical direction.

### Process Furnace of Substrate Processing Apparatus

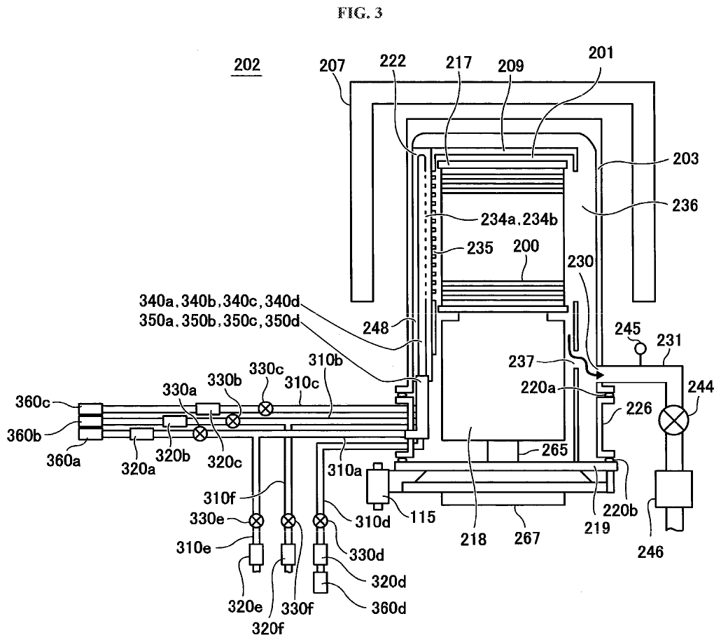

As shown in FIG. 3, the process furnace 202 includes a heater 207 serving as a heating apparatus (heating structure). The heater 207 is of a cylindrical shape, and is vertically installed while being supported by a heater base (not shown) serving as a support plate.

A reaction tube 203 is provided in an inner side of the heater 207 concentrically with the heater 207. A reaction vessel (which is a process vessel) is constituted by the reaction tube 203. For example, the reaction tube 203 is of a cylindrical shape with an open lower end and a closed upper end. The upper end of the reaction tube 203 is closed by a flat wall body. That is, the reaction tube 203 includes a ceiling. Installed in the reaction tube 203 are: a cylindrical structure 209 of a cylindrical shape; a nozzle arrangement chamber 222 partitioned between the cylindrical structure 209 and the reaction tube 203; a plurality of gas supply slits (also simply referred to as “gas supply slits”) 235 serving as a gas supply port provided at the cylindrical structure 209; a first gas exhaust port 236 provided at the cylindrical structure 209; and a second gas exhaust port 237 provided at the cylindrical structure 209 below the first gas exhaust port 236. The cylindrical structure 209 is of a cylindrical shape with an open lower end and a closed upper end. The upper end of the cylindrical structure 209 is closed by a flat wall body. That is, the cylindrical structure 209 includes a ceiling. The cylindrical structure 209 is provided immediately adjacent to the plurality of the wafers including the wafer 200 so as to surround the circumference of the plurality of the wafers. The process chamber 201 is provided in the cylindrical structure 209. The process chamber 201 is configured to accommodate the boat 217 serving as a substrate retainer capable of accommodating (supporting or holding) the plurality of the wafers including the wafer 200 vertically arranged in a horizontal orientation in a multistage manner.

The lower end of the reaction tube 203 is supported by a cylindrical manifold 226. For example, a flange (not shown) is provided at an upper end of the manifold 226, and the lower end of the reaction tube 203 is provided on the flange and supported by the flange. A seal 220a such as an O-ring is provided between the flange and the lower end of the reaction tube 203 to airtightly seal the inside of the reaction tube 203.

The seal cap 219 is airtightly attached to a lower end opening of the manifold 226 via a seal 220b such as an O-ring. The seal cap 219 is configured to airtightly seal a lower end opening of the reaction tube 203, that is, the lower end opening of the manifold 226.

A boat support 218 configured to support the boat 217 is provided on the seal cap 219. The boat support 218 functions not only as a support of supporting the boat 217 but also as a heat insulator. For example, the boat 217 is made of a heat resistant material such as quartz and silicon carbide (SiC). The boat 217 includes a bottom fixed to the boat support 218 and a top plate provided above the bottom plate. A plurality of support columns are provided between the bottom plate and the top plate. The boat 217 is configured to accommodate (support) the plurality of the wafers including the wafer 200. The plurality of the wafers are horizontally oriented with predetermined intervals therebetween. That is, the plurality of the wafers are supported by the plurality of the support columns of the boat 217 with their centers aligned with one another. A stacking direction of the plurality of the wafers is equal to an axial direction of the reaction tube 203.

A boat rotator 267 configured to rotate the boat 217 is provided at the seal cap 219 opposite to the process chamber 201. A rotating shaft 265 of the boat rotator 267 is connected to the boat support 218 through the seal cap 219. As the boat rotator 267 rotates the boat 217 via the boat support 218, the plurality of the wafers including the wafer 200 supported by the boat 217 are rotated.

The seal cap 219 may be elevated or lowered in the vertical direction by the boat elevator 115 provided outside the reaction tube 203. The boat elevator 115 serves as an elevator. As the seal cap 219 is elevated or lowered by the boat elevator 115, the boat 217 is loaded into the process chamber 201 or unloaded out of the process chamber 201.

Nozzle supports 350a, 350b, 350c and 350d, which are configured to support nozzles 340a, 340b, 340c and 340d, are provided at the manifold 226 so as to pass through the manifold 226. Each of the nozzles 340a, 340b, 340c and 340d serves as a gas nozzle. The nozzles 340a through 340d are configured to supply gases such as process gases into the process chamber 201. According to the present embodiment, for example, four nozzle supports including the nozzle supports 350a through 350d are installed. Gas supply pipes 310a, 310b and 310c configured to supply gases such as the process gas into the process chamber 201 are connected to first ends of the nozzle supports 350a, 350b and 350c, respectively. The first ends of the nozzle supports 350a, 350b and 350c are provided lower than second ends of the nozzle supports 350a, 350b and 350c. A gas supply pipe 310d is connected to a first end of the nozzle 340d through the nozzle support 350d. The gas supply pipe 310d is configured to supply a gas such as an inert gas into a gap S provided between the reaction tube 203 and the cylindrical structure 209. The nozzles 340a through 340d are connected to the second ends of the nozzle supports 350a through 350d, respectively.

A first process gas supply source 360a configured to supply a first process gas serving as one of the process gases, a mass flow controller (MFC) 320a serving as a flow rate controller (flow rate control structure) and a valve 330a serving as an opening/closing valve are sequentially provided at the gas supply pipe 310a in order from an upstream side toward a downstream side of the gas supply pipe 310a. A second process gas supply source 360b configured to supply a second process gas serving as one of the process gases, a mass flow controller (MFC) 320b and a valve 330b are sequentially provided at the gas supply pipe 310b in order from an upstream side toward a downstream side of the gas supply pipe 310b. A third process gas supply source 360c configured to supply a third process gas serving as one of the process gases, a mass flow controller (MFC) 320c and a valve 330c are sequentially provided at the gas supply pipe 310c in order from an upstream side toward a downstream side of the gas supply pipe 310c. An inert gas supply source 360d configured to supply the inert gas, a mass flow controller (MFC) 320d and a valve 330d are sequentially provided at the gas supply pipe 310d in order from an upstream side toward a downstream side of the gas supply pipe 310d. Gas supply pipes 310e and 310f configured to supply the inert gas are connected to the gas supply pipes 310a and 310b at downstream sides of the valves 330a and 330b, respectively. Mass flow controllers (MFCs) 320e and 320f and valves 330e and 330f are sequentially provided at the gas supply pipes 310e and 310f in order from upstream sides toward downstream sides of the gas supply pipes 310e and 310f, respectively.

A first process gas supply system is constituted mainly by the gas supply pipe 310a, the MFC 320a and the valve 330a. The first process gas supply system may further include the first process gas supply source 360a, the nozzle support 350a and the nozzle 340a. A second process gas supply system is constituted mainly by the gas supply pipe 310b, the MFC 320b and the valve 330b. The second process gas supply system may further include the second process gas supply source 360b, the nozzle support 350b and the nozzle 340b. A third process gas supply system is constituted mainly by the gas supply pipe 310c, the MFC 320c and the valve 330c. The third process gas supply system may further include the third process gas supply source 360c, the nozzle support 350c and the nozzle 340c. An inert gas supply system is constituted mainly by the gas supply pipe 310d, the WC 320d and the valve 330d. The inert gas supply system may further include the inert gas supply source 360d, the nozzle support 350d and the nozzle 340d.

An exhaust port 230 is provided at the reaction tube 203. The exhaust port 230 is provided below the second gas exhaust port 237. An exhaust pipe 231 is connected to the exhaust port 230. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector configured to detect an inner pressure of the process chamber 201, and the APC valve 244 serves as a pressure regulator. The vacuum pump 246 is configured to vacuum-exhaust an inner atmosphere of the process chamber 201 such that the inner pressure of the process chamber 201 reaches a predetermined pressure. The exhaust pipe 231 provided at a downstream side of the vacuum pump 246 is connected to a component such as an exhaust gas processing apparatus (not shown). The APC valve 244 serves as an opening/closing valve. With the vacuum pump 246 in operation, the APC valve 244 may be opened or closed to vacuum-exhaust the process chamber 201 or to stop the vacuum exhaust. With the vacuum pump 246 in operation, by adjusting an opening degree of the APC valve 244, the APC valve 244 is configured to adjust the inner pressure of the process chamber 201 by adjusting a conductance thereof. An exhaust system serving as an exhaust structure is constituted mainly by the exhaust pipe 231, the APC valve 244 and the pressure sensor 245. The exhaust system may further include the vacuum pump 246.

A temperature sensor (not shown) serving as a temperature detector is provided in the reaction tube 203. The electrical power supplied to the heater 207 is adjusted based on temperature information detected by the temperature sensor such that a desired temperature distribution of an inner temperature of the process chamber 201 is obtained.

In the process furnace 202 described above, in a state where the plurality of the wafers including the wafer 200 to be batch-processed are stacked in the boat 217 in a multistage manner, the boat 217 is inserted into the process chamber 201 while being supported by the boat support 218. The heater 207 heats the plurality of the wafers inserted in the process chamber 201 to a predetermined temperature.

### Configuration of Controller

As shown in FIG. 4, a control system 240 is constituted at least by a controller 121 serving as a main controller, a process system controller “PMC” (Process Module Controller) serving as a recipe execution controller, and a transfer system controller “TM” (Transfer Module Controller) serving as a job execution controller. Hereinafter, the process system controller “PMC” may also be referred to as the recipe execution controller PMC, and the transfer system controller “TM” may also be referred to as the job execution controller TM. In addition, the controller 121 is connected to an input/output device 127 and a memory 128. For example, the input/output device 127 serving as a display may be constituted by components such as a touch panel, and the memory 128 may be constituted by components such as a flash memory and an HDD (Hard Disk Drive).

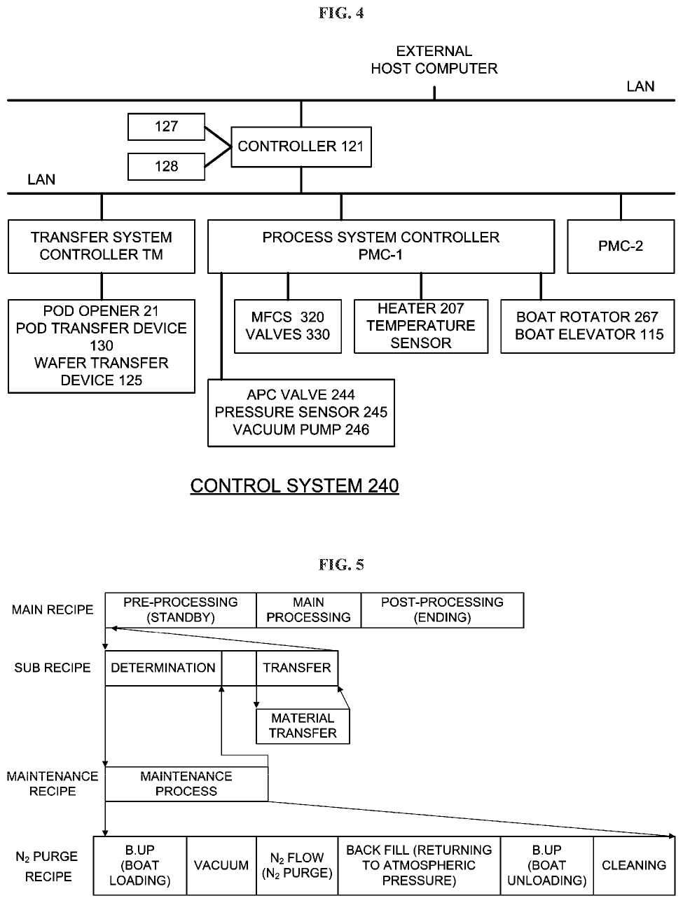

FIG. 4 schematically illustrates the control system 240 when the two processing modules each serving as the process furnace 202 is provided. Hereinafter, the process system controller “PMC” may be simply referred to as a “PMC”. For example, the “PMC-1” and “PMC-2” are connected to the two processing modules each serving as the process furnace 202 shown in FIG. 3, respectively. However, the detailed illustration of the “PMC-2” is omitted in FIG. 5. Hereinafter, the PCM-1 and the PMC-2 may be individually or collectively referred to as the PMC.

A control program (also referred to as a “job”) configured to control the operation of the substrate processing apparatus 10 or a recipe such as a process recipe and a maintenance recipe may be readably stored in the memory 128. The process recipe serving as a film-forming recipe contains information on the sequences and conditions of the substrate processing (also referred to as a “film-forming process”). The process recipe may be obtained by combining steps of the substrate processing described later such that the PMC can execute the steps to acquire a predetermine result. For example, the maintenance recipe may be obtained by combining steps of a maintenance process such that PMC can execute the steps of the maintenance process to maintain components of the substrate processing apparatus 10 without the wafer 200 loaded in the substrate processing apparatus 10.

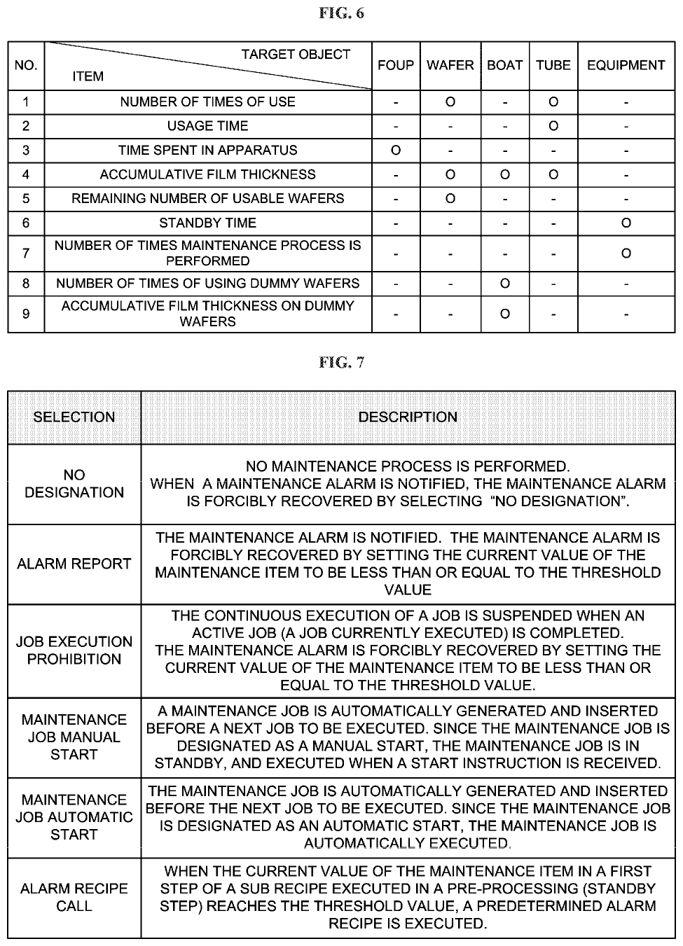

For example, a table indicating maintenance items (refer to FIG. 6) and a table indicating the maintenance process (refer to FIG. 7), which are described later, are stored in the memory 128. The tables relate to the maintenance recipe described above. The controller 121 is configured to read the maintenance recipe and the tables related to the maintenance recipe from the memory 128 and download them to the PMC. The PMC is configured to use data in the tables to execute the maintenance recipe.

The memory 128 is configured to store apparatus data that is generated by operating the components constituting the substrate processing apparatus 10 by executing the job (process job) including the process recipe. Time data is added to the apparatus data by a time stamp function of the controller 121. The same also applies to a job (maintenance job) including the maintenance recipe. Hereinafter, the jobs (that is, the process job and the maintenance job) may be referred to as a “main recipe”. A sub recipe is a recipe that assists the main recipe. For example, the sub recipe may be used when repeatedly performing a predetermined simple step. The recipe described above such as the process recipe functions as a program. In the present specification, the term “program” may indicate the recipe or the control program (job), or both.

According to the present embodiment, by executing the main recipe constituted by three steps (that is, a pre-processing, a main processing and post-processing) by the PMC, a series of processing steps of processing the substrate is performed. According to the present embodiment, the main processing of the main recipe corresponds to the substrate processing. Steps constituting the pre-processing, the main processing (that is, the substrate processing) and the post-processing will be described later.

According to the present embodiment, the maintenance recipe may include recipes such as a purge recipe, a warm-up recipe and a cleaning recipe. For example, the maintenance recipe may be selected from the purge recipe, the warm-up recipe and the cleaning recipe, and executed appropriately according to the contents of an error. In addition, the maintenance recipe may be set in advance according to a location (component) where the error has occurred. Control parameters such as a temperature, a gas flow rate, electric power and a pressure related to the process furnace 202 (that is, the process chamber 201) may be appropriately set according to the contents of the maintenance recipe when the maintenance recipe is executed.

In the present specification, the apparatus data refers to data collected when the job is executed as described above. For example, the apparatus data may include data generated when the substrate processing apparatus 10 operates each component to process the wafer 200. For example, the apparatus data may include: data on the substrate processing (for example, pre-set values and actual measured values) such as a process temperature, a process pressure and flow rates of the process gases when the substrate processing apparatus 10 processes the wafer 200 (that is, when the process recipe is executed); data on a quality of a manufactured product substrate (for example, a thickness of a film formed on the wafer 200 and an accumulated thickness of the film); and data such as component data on the components constituting the substrate processing apparatus 10 (for example, the reaction tube 203, the heater 207, the valves 330a through 330f and the MFCs 320a through 320f). Similarly, the apparatus data may include data generated when the substrate processing apparatus 10 operates each component to maintain the substrate processing apparatus (that is, when the maintenance recipe is executed).

The controller 121 is configured to read the process recipe (or the maintenance recipe) stored in the memory 128 in accordance with an instruction such as an operation command inputted via the input/output device 127. The controller 121 is configured to control the operations of the components of the substrate processing apparatus 10 through the PMC in accordance with the contents of the read process recipe. For example, the controller 121 is configured to control various operations such as flow rate adjusting operations for various gases by the MFCs 320a through 320f, opening/closing operations of the valves 330a through 330f, an opening/closing operation of the APC valve 244, a pressure adjusting operation by the APC valve 244 based on the pressure sensor 245, a start and stop of the vacuum pump 246, a temperature adjusting operation of the heater 207 based on the temperature sensor (not shown), an operation of adjusting rotation and rotation speed of the boat 217 by the boat rotator 267 and an elevating and lowering operation of the boat 217 by the boat elevator 115.

In addition, the controller 121 is configured to control the operations of the components of the substrate processing apparatus 10 through the transfer system controller in accordance with the contents of the process job. For example, the controller 121 is configured to control various operations such as a transfer operation of the pod 110 among the loading port 22, the pod shelves 105, and the pod opener 21 by the pod transfer device 130, a cap attaching and detaching operation of the pod 110 placed on the placement table 122 by the pod opener 21, and a operation of loading (charging) and unloading (discharging) the wafer 200 placed on the tweezers 125c (which is a substrate holder) of the wafer transfer device 125 into or out of the boat (substrate retainer) 217 serving as the placement container for the wafer 200 by the consecutive operations of the wafer transfer structure 125a and the wafer transfer structure elevator 125b.

### Substrate Processing

Subsequently, the substrate processing will be described with reference to FIG. 3. The boat 217 with a predetermined number of wafers including the wafer 200 placed thereon is inserted into the reaction tube 203 (boat loading step), and the reaction tube 203 is airtightly sealed by the seal cap 219. The wafer 200 is heated in the reaction tube 203 airtightly sealed, and the process gases are supplied into the reaction tube 203 to perform a predetermined processing to the wafer 200.

As the predetermined processing, for example, PH₃ gas serving as the first process gas and SiH₄ gas serving as the second process gas are simultaneously supplied into the reaction tube 203 to form a silicon film on the wafer 200.

First, the PH₃ gas is supplied through the gas supply pipe 310a of the first process gas supply system into the process chamber 201 via a plurality of gas supply holes 234a of the nozzle 340a and the gas supply slits 235, and the SiH₄ gas is supplied through the gas supply pipe 310b of the second process gas supply system into the process chamber 201 via a plurality of gas supply holes 234b of the nozzle 340b and the gas supply slits 235. Specifically, by opening the valves 330a, 330b, 330e and 330f, the PH₃ gas is supplied through the gas supply pipe 310a and the SiH₄ gas is supplied through the supply pipe 310b into the process chamber 201 together with the carrier gas. When the PH₃ gas and the SiH₄ gas is supplied into the process chamber 201, the opening of the APC valve 244 is adjusted to maintain the inner pressure of the process chamber 201 at a predetermined pressure. After a predetermined time has elapsed, the valves 330a and 330b are closed to stop the supply of the SiH₄ gas and the supply of the PH₃ gas.

The SiH₄ gas and the PH₃ gas supplied into the process chamber 201 are supplied to the plurality of the wafers including the wafer 200, flow in a direction parallel to upper surfaces of the plurality of the wafers, then flow from an upper portion of the gap S to a lower portion of the gap S through the first gas exhaust port 236. Then, the SiH₄ gas and the PH₃ gas are exhausted through the exhaust pipe 231 via the second gas exhaust port 237 and the exhaust port 230.

After the supply of the SiH₄ gas and the supply of the PH₃ gas into the process chamber 201 are stopped by closing the valves 330a and 330b, the vacuum pump 246 vacuum-exhausts the inner atmosphere of the process chamber 201 to remove substances such as a residual SiH₄ gas, a residual PH₃ gas in the process chamber 201 and reaction by-products. In addition, the inert gas such as N₂ gas may be further supplied into the process chamber 201 and the gap S through the gas supply pipes 310a, 310b, 310c and 310d to purge the process chamber 201 and the gap S, which improves the efficiency of removing the substances such as the residual SiH₄ gas, the residual PH₃ gas in the process chamber 201 and the reaction by-products from the process chamber 201 and the gap S (N₂ purge step).

After the predetermined processing of the wafer 200 is completed, the boat 217 is unloaded (transferred) out of the reaction tube 203 boat unloading step) in an order reverse to that of loading the boat 217 into the reaction tube 203 (boat unloading step).

For example, process conditions of forming the silicon film are as follows:
Silicon source: SiH₄ (monosilane);
Film-forming temperature: 520° C.;
Pressure: 0.68 Torr;
Flow rate of the gas: 2.8 SLM (monosilane); and
Film-forming time: about 15 minutes.

In the present embodiment, the first process gas and the second process gas are simultaneously supplied. However, the present embodiment is not limited thereto. The present embodiment may also be applied when the first process gas and the second process gas are alternately supplied.

Subsequently, a process flow of executing the process job (that is, the main recipe) according to the present embodiment, in particular, a process flow of enabling the maintenance process to be performed in a first step (leading step) of the pre-processing will be described in detail with reference to FIG. 5 through FIG. 9.

As shown in FIG. 5, the process job is the main recipe including the pre-processing (standby step), the main processing (film-forming step) and the post-processing (ending step). According to the present embodiment, an alarm process (maintenance process) can be performed in the first step (leading step) of the pre-processing. The alarm process may also be referred to as a “alarm recovery process”. According to the present embodiment, the pre-processing is a step of preparing the main processing. For example, the pre-processing may at least include: a step of preparing a process environment (process atmosphere) in the process furnace 202; a step of loading the plurality of the wafers including the wafer 200 into the boat 217 (wafer charging step); and a step of a preparing a transfer environment (transfer atmosphere) in which the boat 217 and the plurality of the wafers are in standby below the process furnace 202.

Specifically, for example, the sub recipe is executed in the first step of the pre-processing, and the maintenance process is performed in a first step of the sub recipe. In the pre-processing, for example, the maintenance process refers to a maintenance recipe of maintaining components provided in the process furnace 202 (or constituting the process furnace 202) in which the wafer 200 is processed. The maintenance process will be described later in detail.

As shown in FIG. 6, maintenance items are set for each target object such as a target component. In addition, the maintenance items may be appropriately set on a screen of the display (that is, the input/output device 127) by displaying the maintenance items on the display.

Referring to FIG. 6, for example, the pod 110 (“FOUP”), the wafer 200 (“WAFER”), the boat 217 (“BOAT”), the reaction tube 203 (“TUBE”) and the substrate processing apparatus 10 (“EQUIPMENT”) are set as the target objects described above.

Referring to FIG. 6, for example, the following may be set up as the maintenance items: “NUMBER OF TIMES OF USE” indicating the number of times that the target object is used; “USAGE TIME” indicating the amount of time that the target object is used; “TIME SPENT IN APPARATUS” indicating the amount of time that the target object has spent in the substrate processing apparatus; “ACCUMULATIVE FILM THICKNESS” indicating an accumulative thickness of the film registered in advance; “REMAINING NUMBER OF USABLE WAFERS” indicating the number of useable substrates (wafers) remaining; “STANDBY TIME” indicating a standby time of the target object; “NUMBER OF TIMES MAINTENANCE PROCESS IS PERFORMED” indicating the number of times that the maintenance process is performed; “NUMBER OF TIMES OF USING DUMMY WAFERS” indicating the number of times that dummy wafers are used; and “ACCUMULATIVE FILM THICKNESS ON DUMMY WAFERS” indicating an accumulative thickness of the film formed on the dummy wafers. The maintenance items and the components (objects) in the maintenance items is configured such that it is possible to appropriately add a component (object) into the maintenance items or to appropriately delete a maintenance item from the maintenance items. In FIG. 6, the symbol “-” indicates that the setting of the maintenance item with respect to the component (object) is invalid, and the symbol “0” indicates that the setting of the maintenance item with respect to the component (object) is valid. It is possible to set (or edit) the symbol “0” and the symbol “-” appropriately.

For example, when the maintenance item of a target object (also simply referred to as a “target”) “EQUIPMENT” is “STANDBY TIME”, the “STANDBY TIME” refers to a time during which the substrate processing apparatus 10 is in standby (IDLE). Therefore, when the substrate processing apparatus 10 performs a processing such as the main processing without being suspended, “STANDBY TIME” is set to zero (0) minute. Further, when there is no lot to be processed next, the substrate processing apparatus 10 enters into standby (that is, into an idle state) after processing the wafer 200. For example, when the standby time of the substrate processing apparatus 10 reaches 1 hour, an in-furnace cyclic purge recipe is executed as the maintenance process. In such a case, a threshold value of performing the maintenance process is set to 1 hour in advance.

For example, when the maintenance item of a target object “TUBE” is “NUMBER OF TIMES OF USE”, “NUMBER OF TIMES OF USE” refers to the number of times that the process such as the main processing is performed in the process furnace 202. For example, when a specific step in the recipe has been completed, “NUMBER OF TIMES OF USE” is increased by 1. When the number of times that the process is performed reaches a predetermined threshold value, the maintenance process is performed. For example, the in-furnace cyclic purge recipe or the cleaning recipe may be executed as the maintenance recipe when the maintenance process is performed.

For example, when the maintenance item of a target object “BOAT” is “ACCUMULATIVE FILM THICKNESS”, “ACCUMULATIVE FILM THICKNESS” (that is, an accumulative thickness of the film of the boat 217) refers to the accumulative thickness value of the film registered in advance with respect to a specific step in the recipe in a case where the specific step in the recipe is performed with the boat 217 inserted in the process furnace 202. When the accumulative thickness of the film reaches a predetermined threshold value, the maintenance process is performed. For example, the cleaning recipe is executed as the maintenance recipe when the maintenance process is performed.

For example, the maintenance process for each maintenance item set to the symbol “O” in FIG. 6 is defined in FIG. 7. For example, as selective options of the maintenance process, “NO DESIGNATION”, “ALARM REPORT”, “JOB EXECUTION PROHIBITION”, “MAINTENANCE JOB MANUAL START”, “MAINTENANCE JOB AUTOMATIC START” and “ALARM RECIPE CALL” are shown in FIG. 7. A timing of performing the maintenance process may be appropriately determined depending on the maintenance item and the maintenance process. Thereby, it is possible to selectively use the maintenance process as the post-processing after the film-forming process is completed and the maintenance process as the pre-processing before the film-forming process is started, and it is also possible to efficiently perform the maintenance process.

When “NO DESIGNATION” shown in FIG. 7 is selected, the maintenance process is not performed. When the maintenance process is changed to “NO DESIGNATION” while the alarm is being notified, the alarm will be recovered. For example, when a trivial alarm is generated, “NO DESIGNATION” can be selected to forcibly recover the alarm and continue the processing.

Subsequently, when “ALARM REPORT” is selected, the alarm is notified. In the maintenance process, the alarm can be recovered by setting the current value of the maintenance item of the target object to be less than or equal to the threshold value. The error is set as a minor error that triggers a notification but is not enough to stop the processing.

When “JOB EXECUTION PROHIBITION” is selected, the execution of the next job is suspended at the timing when the job currently executed is completed. In the maintenance process, the alarm can be recovered and the next job can be executed by setting the current value of the maintenance item of the target object to be less than or equal to the threshold value.

When “MAINTENANCE JOB MANUAL START” is selected, the maintenance job is automatically generated and interrupts before the next job to be executed. Since the maintenance job is designated as a manual start, the maintenance job is in standby. When a start instruction is received, the maintenance job is executed. When the maintenance job is terminated normally, the alarm can be recovered. When the maintenance job is terminated abnormally, the alarm is not recovered. In such a case, the alarm can be recovered by setting the current value of the maintenance item of the target object to be less than or equal to the threshold value. The details of “MAINTENANCE JOB AUTOMATIC START” are the same as those of “MAINTENANCE JOB MANUAL START” except that the maintenance job is automatically executed without waiting for the start instruction unless there is another job being executed.

When “ALARM RECIPE CALL” is selected, a predetermined alarm recipe may be executed. Specifically, the predetermined alarm recipe is executed when the current value of the maintenance item of the target object in the first step of the sub recipe executed in a standby step serving as the pre-processing reaches the threshold value. Then, the alarm can be recovered when the predetermined alarm recipe is terminated normally, and the alarm can be recovered when the predetermined alarm recipe is terminated abnormally. When the current value of the maintenance item of the target object does not reach the threshold value, no alarm recipe is executed, and the next step is automatically executed.

The contents of the maintenance process defined in FIG. 7 are configured such that it is possible to appropriately change, delete or add the contents of the maintenance process in a manner similar to the maintenance items shown in FIG. 6. In addition, similar to the maintenance items shown in FIG. 6, the contents of the maintenance process shown in FIG. 7 may be appropriately set on the screen of the display (that is, the input/output device 127) by displaying the contents of the maintenance process on the display. In addition, the contents of the maintenance recipe including the alarm recipe are not limited to the boat loading step, the maintenance process, and the boat unloading step. For example, a maintenance recipe of removing the particles in the vicinity of the rotating shaft 265 of the boat rotator 267 includes the main processing (the boat loading step, the N2 purge step and the boat unloading step) and a cooling step. Details of the maintenance recipe of removing the particles in the vicinity of the rotating shaft 265 will be described later.

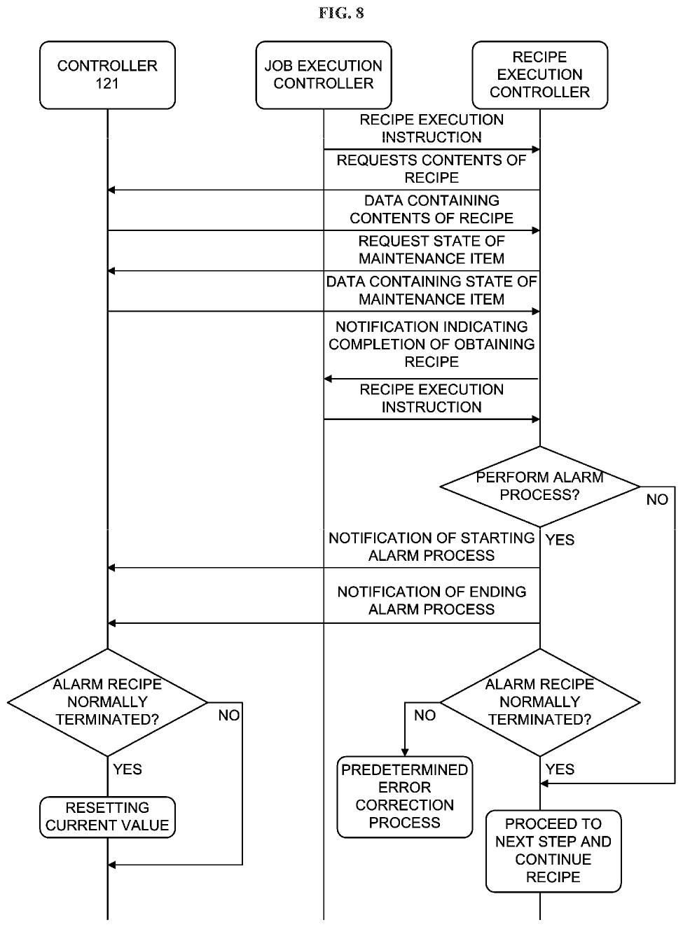

FIG. 8 illustrates a sequence of the first step of the sub recipe executed in the pre-processing shown in FIG. 5 in detail. As shown in FIG. 8, the job execution controller TM sends a first recipe execution instruction to the recipe execution controller PMC. The recipe execution controller PMC requests the contents of the recipe (the contents of the process recipe) to the controller 121, and the controller 121 transmits data containing the contents of the recipe (the contents of the process recipe) to the recipe execution controller PMC.

Subsequently, according to the present embodiment, the recipe execution controller PMC may request the controller 121 the state (status) of the maintenance item, and the controller 121 may transmit data containing the state of the maintenance item (for example, the current value) to the recipe execution controller PMC. Then, the recipe execution controller PMC may notify the job execution controller TM of the completion of obtaining the recipe when the recipe execution controller PMC receives the data containing the state of the maintenance item, and the execution controller TM that has received a notification indicating the completion of obtaining the recipe may transmit a second recipe execution instruction to the recipe execution controller PMC. According to the present embodiment, a maintenance processing method for each maintenance item is stored as the contents of the data containing the state of the maintenance item for each maintenance item. When “ALARM RECIPE CALL” shown in FIG. 7 is selected, information on whether to perform the maintenance process is stored according to the present embodiment. On the other hand, when “ALARM RECIPE CALL” shown in FIG. 7 is not selected as the maintenance process, the sub recipe may not be executed. In addition, the information on whether to perform the maintenance process may include information indicating whether the current value of the maintenance item reaches the threshold value. When the current value does not reach the threshold value, the sub recipe may not be executed.

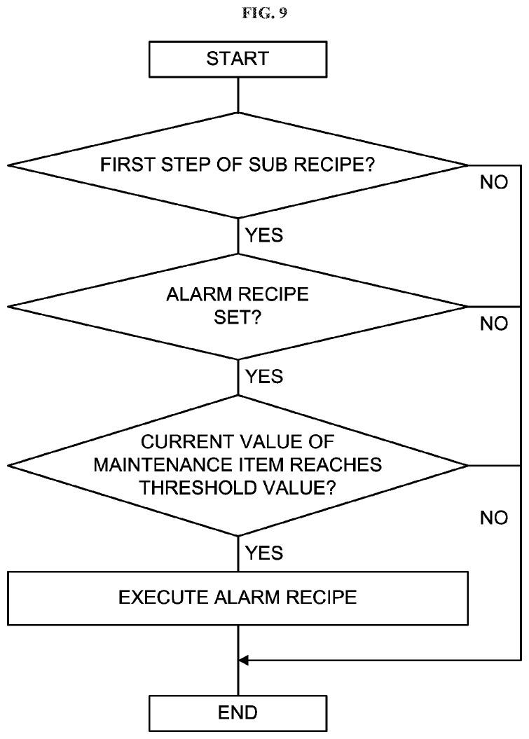

Subsequently, a step (determination step) of determining whether to perform the alarm process shown in FIG. 9 is performed. The recipe execution controller PMC is configured to confirm the setting of executing the maintenance recipe serving as the alarm recipe, to compare the current value of the pre-set maintenance item with the threshold value, and to confirm whether the current value reaches the threshold value. When the current value reaches the threshold value, the recipe execution controller PMC executes the maintenance recipe. When the current value does not reach the threshold value, the recipe execution controller PMC ends the determination step without executing the maintenance recipe.

As shown in FIG. 8, when the current value of the pre-set maintenance item reaches the threshold value, the recipe execution controller PMC transmits a notification of starting the process to the controller 121 at the start of the execution of the alarm recipe, and transmits a notification of ending the process to the controller 121 at the end of the execution of the alarm recipe. When the current value of the pre-set maintenance item does not reach the threshold value, which is a determination that the maintenance recipe may not be executed, the recipe execution controller PMC is configured to proceed to the next step and continue the recipe.

The recipe execution controller PMC is configured to perform a predetermined error correction process when the alarm recipe is not normally terminated. The predetermined error correction process is configured to forcibly shift (jump) to the post-processing and perform the post-processing, for example. In such a case, the recipe execution controller PMC omits (skips) the sub recipe (a cooling process or a wafer recovery process) shown in FIG. 5, and sets the process such as the pre-processing into a temporary stop state. Alternatively, the recipe execution controller PMC executes an abort recipe to perform an abort process. Even in such a case, the recipe execution controller PMC sets the process into the temporary stop state. In both cases described above, the process of correcting the occurred failure (error) is performed, and then the production processing resumes.

When the alarm recipe is terminated normally, the next step following the first step of the sub recipe is performed. As shown in FIG. 5, the sub recipe further includes a transfer step of transferring the substrate (that is, the wafer 200). That is, the sub recipe is configured to perform the transfer step of transferring the wafer 200 into the boat 217. In addition, when the transfer step is terminated normally, the recipe execution controller PMC sets the process such as the pre-processing into the temporary stop state in a manner described above. Then, when the transfer step is completed, the execution of the sub recipe is terminated, and a second step of the main recipe is started. Then, the main processing (film-forming step) is started. Since the main processing is already described above, the description of the main processing is omitted.

The controller 121 is further configured to reset the current value of the pre-set maintenance item to zero (0) when the alarm recipe is normally terminated. As a result, the controller 121 is configured to cancel the alarm generated by the maintenance item set for the target object. For example, when the job is reserved in advance to be executed twice consecutively (that is, a first job and a second the same as the first job are performed as the job), even if the threshold value is reached at the end of the first job, the second job may be executed with the inner atmosphere of the process furnace 202 being adjusted when the alarm recipe is executed in the first step of the pre-processing of the second job and the alarm recipe is normally terminated.

Then, the post-processing (ending step) is preformed after the film-forming step is performed. For example, the post-processing may at least include: a step of preparing the process environment in the process furnace 202 for the next film-forming step; a step (cooling step) of cooling the boat 217 and the plurality of the wafers including the wafer 200 which have been processed; and a step (transfer step) of collecting the plurality of the processed wafers including the wafer 200 from the boat 217 (wafer discharging step).

Specifically, for example, as shown in FIG. 5, the sub recipe is executed in a first step of the post-processing. For example, the sub recipe executed in the first step of the post-processing may at least include: the cooling step of cooling the boat 217 and the plurality of the processed wafers including the wafer 200; and the transfer step of collecting the plurality of the processed wafers including the wafer 200 from the boat 217. Then, when the execution of the sub recipe is completed, the recipe execution controller PMC proceeds to the next step of the post-processing, and a process of preparing the process environment in the process furnace 202 for the next film-forming process is performed.

### First Example of Present Embodiment

Subsequently, the operation of the substrate processing apparatus 10 will be described. According to a first example of the present embodiment, when it comes the time to start an execution process of the process job reserved, the controller 121 controls the operations of the components constituting the substrate processing apparatus 10 to start the process job.

In the first step (leading step) of the pre-processing (which is performed before the plurality of the wafers including the wafer 200 are transferred), the controller 121 performs the step (determination step) of determining whether to perform the maintenance process. Specifically, the recipe execution controller PMC determines whether to perform the maintenance process. For example, the threshold value executed by the recipe execution controller PMC is compared with the pre-set current value of the maintenance item. According to the first example of the present embodiment, it is compared whether or not the pre-set current value of the maintenance item reaches the threshold value of executing the alarm recipe. The comparison described above may be performed for the maintenance item among the maintenance items set to “O” in FIG. 6 and set to “ALARM RECIPE CALL” shown in FIG. 7.

When the current value does not reach the threshold value of executing the alarm recipe, it is determined that the maintenance process may not be performed, and the recipe execution controller PMC proceeds to the next step and continues the sub recipe. In such a case, the recipe execution controller PMC notifies the transfer system controller serving as the job execution controller of the completion of the first step of the sub recipe. When the current value reaches the threshold value of executing the alarm recipe, it is determined that the maintenance process should be performed, and the recipe execution controller PMC performs the maintenance process in the first step of the sub recipe (by calling the alarm recipe). When the recipe execution controller PMC performs the maintenance process, the recipe execution controller PMC transmits an alarm process start notification to the controller 121 at the start of the alarm process, and transmits an alarm process end notification to the controller 121 at the end of the alarm process.

When the alarm recipe is terminated normally, as described above, the recipe execution controller PMC proceeds to the next step and continues the sub recipe. The controller 121 resets the current value of the pre-set maintenance item to zero (0), and cancels the alarm generated.

When the alarm recipe is terminated abnormally, the recipe execution controller PMC sets the apparatus such as the substrate processing apparatus 10 into a temporary stop state by performing the predetermined error correction process. In addition, the controller 121 is configured to hold the alarm while maintaining the current value of the pre-set maintenance item.

The transfer system controller that has received a notification of the end of the first step (that is, the alarm process end notification described above) is configured to perform the transfer step of transferring the plurality of the wafers including the wafer 200 into the boat 217. That is, the transfer step of transferring the plurality of the wafers including the wafer 200 into the boat 217 is performed by the transfer system controller as the transfer step of the pre-processing. When the pod 110 is placed on the loading port 22, the pod 110 placed on the loading port 22 is transferred into the housing 111 through the pod loading/unloading port (not shown) by a pod loading device. Then, the pod 110 transferred into the housing 111 is automatically transferred to and temporarily stored in a designated placement plate among the placement plates 140 of the pod shelves 105 by the pod transfer device 130. The pod 110 is then transferred toward one of the upper and lower pod openers 21 from the designated placement plate and placed on the placement table 122. Alternatively, the pod 110 may be directly transferred toward the one of the upper and lower pod openers 21 and placed on the placement table 122.

When the wafer entrance of the pod 110 placed on the placement table 122 is pressed against one of the pair of the wafer loading/unloading ports 120 of the front wall 119a of the sub-housing 119, the cap attaching/detaching structure 123 detaches the cap of the pod 110 and the wafer entrance of the pod 110 is opened. When the pod 110 is opened by the one of the upper and lower pod openers 21, the wafer 200 is then transferred out of the pod 110 by the tweezers 125c of the wafer transfer structure 125a through the wafer entrance of the pod 110, transferred into the loading chamber 6 provided in the rear region of the transfer chamber 8 via the gate valve 90, and loaded (charged) into the boat 217 (wafer charging). When the wafer 200 is charged, the wafer 200 may be aligned by a notch alignment device (not shown). After the wafer 200 is charged into the boat 217, the wafer transfer structure 125a then returns to the pod 110 and transfers a next wafer among the plurality of the wafers from the pod 110 into the boat 217.

While the wafer transfer device 125 loads the wafer 200 from the one of the upper and lower pod openers 21 into the boat 217, another pod 110 is transferred by the pod transfer device 130 to the other one of the upper and lower pod openers 21, and the cap of the aforementioned another pod 110 is opened.

When a predetermined number of wafers including the wafer 200 are charged into the boat 217, the process recipe (that is, the main processing) is executed. The process recipe is a recipe configured to process the substrate (that is, the wafer 200), and the execution of the process recipe is controlled by the controller 121. When the process recipe is started, the lower end opening of the process furnace 202 is opened by the furnace opening shutter 147. Then, the seal cap 219 is elevated by the boat elevator 115, and the boat 217 accommodating the plurality of the wafers including the wafer 200 is loaded (inserted) into the process furnace 202.

After the boat 217 is loaded into the process furnace 202, the plurality of the wafers including the wafer 200 are appropriately processed in the process furnace 202. After the plurality of the wafers are processed, the plurality of the wafers and the pod 110 are unloaded out of the housing 111 in an order reverse to that of loading the pod 110 and the plurality of the wafers described above.

### Comparative Example

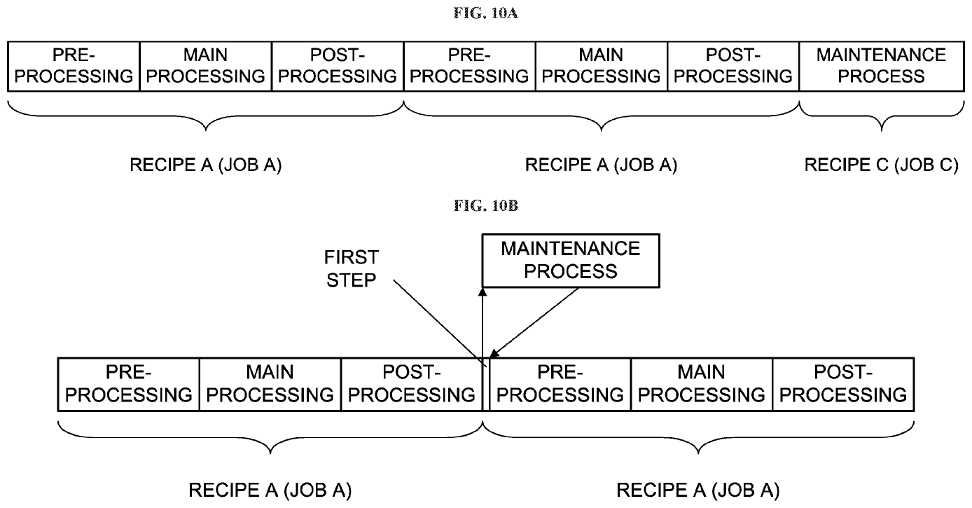

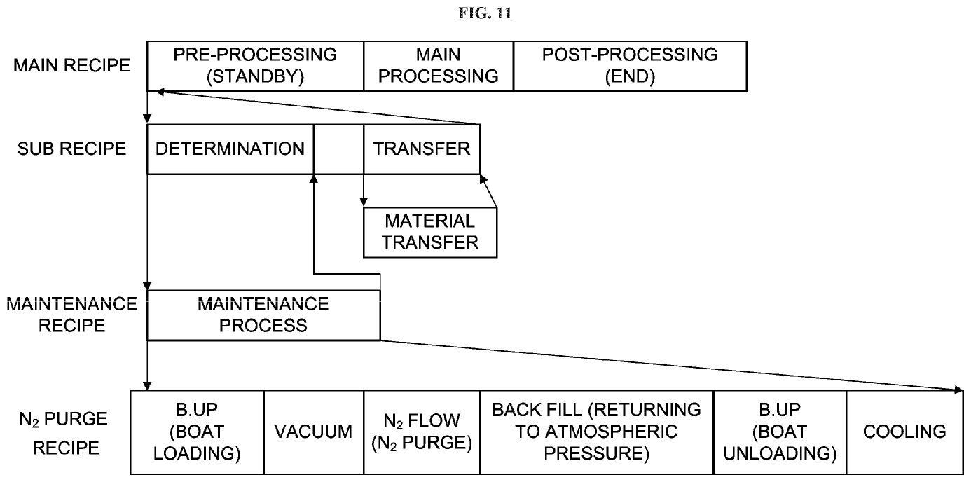

As shown in FIG. 10A, according to a comparative example, the film-forming process is performed a plurality of times in a single job (for example, when N wafers are divided into two sets of N/2 wafers, and the film-forming process is performed twice in the single job) and the film-forming process is continuously performed in the same process chamber 201 (or in the same process furnace 202). According to the maintenance process of the comparative example, since there is no “ALARM RECIPE CALL” shown in FIG. 7, the process recipe is executed twice continuously while a single process job is executed even if “MAINTENANCE JOB AUTOMATIC START” has been set up. That is, a first process recipe and a second process recipe which is the same as the first process recipe are executed continuously as the process recipe in the single process job. Therefore, even when the apparatus (for example, the controller 121 of the substrate processing apparatus 10) recognizes (or determines) that a scheduled maintenance threshold is reached during the execution of the first process recipe and the maintenance process should be performed, the maintenance recipe by the maintenance job cannot be executed unless the execution of the second process recipe is completed (that is, the process job is terminated). Therefore, even when the controller 121 recognizes (or determines) that the result of the substrate processing is bad, the process recipe should be executed twice continuously. As a result, there is a concern that a reliability of the result of the substrate processing may be reduced.

### Second Example of Present Embodiment

As shown in FIG. 10B, according to a second example of the present embodiment, the film-forming process is performed a plurality of times in a single job (for example, when N wafers are divided into two sets of N/2 wafers, and the film-forming process is performed twice in the single job) and the film-forming process is continuously performed in the same process chamber 201 (or in the same process furnace 202). However, according to the second example of the present embodiment, by setting up “ALARM RECIPE CALL” shown in FIG. 7, it is possible to execute the maintenance process at the first step of the pre-processing of the second process recipe described above.

### Third Example of Present Embodiment

When the silicon film is formed on the wafer 200, if a batch process of forming the silicon film is performed a predetermined number of times, the particles may be generated in the vicinity of the rotating shaft 265 of the boat rotator 267. According to a third example of the present embodiment, “ALARM RECIPE CALL” shown in FIG. 7 is set up in the maintenance process, and the number of times that the wafer 200 (“WAFER” in FIG. 6) is used and the number of times that the reaction tube 203 (“TUBE” in FIG. 6) is used are set as the maintenance item “NUMBER OF TIMES OF USE” shown in FIG. 6. Specifically, when at least one among the number of times that the wafer 200 (“WAFER”) is used and the number of times that the reaction tube 203 (“TUBE”) is used reaches the threshold number of times of use, a particle reduction recipe serving as the maintenance process (alarm recipe) of reducing the particles is executed. For example, a N2 purge recipe shown in FIG. 11 is executed.

As shown in FIG. 11, for example, the N₂ purge recipe includes the main processing (the boat loading step, the N2 purge step and the boat unloading step) and the cooling step. In addition, FIG. 11 illustrates an example in which the maintenance recipe (maintenance process) shown in FIG. 5 is implemented, and other recipes such as the main recipe are exactly the same as those shown in FIG. 5.

Therefore, in FIG. 11, the description of portions that are the same as the embodiment shown in FIG. 5 is omitted. In the third example of the present embodiment, the N₂ purge recipe shown in FIG. 11 serving as the maintenance process (alarm recipe) will be described.

In the boat loading step of the N₂ purge recipe, the boat 217 is inserted into the process furnace 202 in a manner similar to the boat loading step of the maintenance recipe described above. However, in the boat loading step of the N₂ purge recipe, the boat 217 where the plurality of the wafers including the wafer 200 are not accommodated (that is, an empty boat) is inserted into the process furnace 202. Alternatively, in the boat loading step of the N₂ purge recipe, the boat 217 may not be inserted into the process furnace 202, or the boat 217 accommodating one or more wafers for the in-furnace adjustment other than product wafers may be inserted into the process furnace 202. It is possible to appropriately set the presence/absence of the boat 217 and the presence/absence of loading of the wafers into the boat 217 in the boat loading step of the N₂ purge recipe.

Then, a pressure adjusting step of adjusting the inner pressure of the process furnace 202 (that is, the inner pressure of the process chamber 201) to a predetermined pressure is performed. In the pressure adjusting step, the inner temperature of the process furnace 202 (that is, the inner temperature of the process chamber 201) is also adjusted to a predetermined temperature. According to the present embodiment, the inner pressure and the inner temperature of the process furnace 202 (process chamber 201) are maintained at the predetermined pressure and the predetermined temperature, respectively, in the subsequent the N₂ purge step or a returning to atmospheric pressure step.

Then, while the inner pressure and the inner temperature of the process furnace 202 (process chamber 201) are maintained at the predetermined pressure and the predetermined temperature, respectively, the N₂ purge step is performed. In the N₂ purge step, a purge gas (that is, the inert gas) is supplied into the process furnace 202 (process chamber 201). Specifically, the inert gas is supplied into the process furnace 202 (process chamber 201) through the inert gas supply system. The valves 330a, 330b and 330c of the first process gas supply system, the second process gas supply system and the third process gas supply system are closed. In the N₂ purge step, the valves 330e and 330f of the second process gas supply system and the third process gas supply system may be opened to supply the inert gas into the process furnace 202 (process chamber 201). In the N₂ purge step, a flow rate of the purge gas supplied in the vicinity of the rotating shaft 265 of the boat rotator 267 is set to be a large amount.

For example, purge conditions of the N₂ purge recipe are as follows:
Purge gas: N₂ gas;
Temperature: 400° C.; and
Pressure: 0.006 Torr.

Then, when the inert gas is supplied for a certain period of time while the inner pressure and the inner temperature of the process furnace 202 (process chamber 201) are maintained at the predetermined pressure and the predetermined temperature, respectively, the returning to atmospheric pressure step is performed. In the returning to atmospheric pressure step, the purge gas is supplied into the process furnace 202 (process chamber 201) until the inner pressure of the process furnace 202 (process chamber 201) reaches the atmospheric pressure. Similarly, the inner temperature of the process furnace 202 (process chamber 201) is also lowered.

When the inner temperature of the process furnace 202 (process chamber 201) is lowered to a certain level (for example, a standby temperature), the boat unloading step is performed. In the boat unloading step, the boat 217 is transferred out of the process furnace 202 (process chamber 201).

After the boat 217 is unloaded, at least, the step (cooling step) of cooling the boat 217 is preformed. The cooling step is performed because the boat 217 may be unloaded out of the process furnace 202 (process chamber 201) while a temperature of the boat 217 is high depending on the temperature during the N₂ purge step. According to the third example of the present embodiment, the cooling step is provided because the temperature during the N₂ purge step is relatively high. Specifically, since the temperature, which is one of the purge conditions of the N₂ purge recipe described above, is as high as 400° C., when the transfer step is performed without performing the cooling step, a transfer failure may occur during the wafer 200 is transferred in the transfer step. In the cooling step, a pre-set time is set up. However, a temperature sensor (not shown) may be provided in the loading chamber 6 and the cooling step may be terminated when a temperature detected by the temperature sensor is lower than a predetermined temperature. For example, a total time of the N₂ purge recipe is about 15 minutes.

Then, when the N₂ purge recipe is completed, the next step of the determination step of the sub-recipe is performed. Thereafter, the transfer step of transferring the plurality of the wafers including the wafer 200 is performed. Since the subsequent steps are the same as those shown in FIG. 5, the description thereof will be omitted.

According to the third example of the present embodiment, in order to reduce the particles that greatly affect the result of the substrate processing, the alarm recipe is set to be executed when the number of times of the use of either the wafer 200 or the reaction tube 203 reaches the threshold value. However, the setting of the alarm recipe is not limited thereto. For example, the maintenance items shown in FIG. 6 and the maintenance process shown in FIG. 7 may be appropriately determined in accordance with the contents of the maintenance. In addition, the maintenance recipe in the third example of the present embodiment may be configured by a combination of the main processing (the boat loading step, a processing step such as the N₂ purge step and the boat unloading step) and the cooling step of cooling the boat 217 and the plurality of the wafers including the wafer 200. As described above, the maintenance recipe incorporated in the pre-processing is not limited to the configuration of the main processing (the boat loading step, the processing step such as the N₂ purge step and the boat unloading step), and is configured to be appropriately set according to the contents of the maintenance.

By executing the N₂ purge recipe as described above, it is possible to remove the particles in the vicinity of the rotating shaft 265. For example, it is possible to blow off the particles stagnant in a dead space of a seal cover (that is, the seal cap 219) with a large flow of the inert gas.

According to the present embodiment, it is possible to provide one or more advantageous effects (a) through (f) described below.

(a) Conventionally, even when the maintenance recipe is executed after the current process job is executed, the result of the substrate processing of a first batch of the process job becomes worse (the result of the substrate processing is stabilized from a second batch of the process job) if it takes a longer time until the next process job is started (hereinafter, also referred to as a “waiting time”). However, according to the present embodiment, by executing the maintenance recipe in the first step (leading step) of the pre-processing of the process job, it is possible to stabilize the result of the substrate processing from the first batch.

(b) According to the present embodiment, since the maintenance recipe is executed at the first step of the pre-processing of the process job, the process recipe executed in the main processing is not so affected that the effect on the result of the substrate processing result is extremely small. In particular, even when the batch process is continuously performed, it is possible to stabilize the result of the substrate processing because the time left until the process recipe is started is always constant when the maintenance recipe is executed. On the other hand, according to the comparative example in which the next process job is performed after completing the execution of the maintenance recipe, the maintenance recipe is executed while it is uncertain whether an execution instruction of the process job has been issued after the maintenance recipe is completed. Thus, the time taken to execute the process recipe will be different depending on the timing of the execution instruction of the process job, and the result of substrate processing may be adversely affected.

(c) According to the present embodiment, since the maintenance process can be included in the first step (leading step) of the pre-processing of the process job for production processing, it is possible to execute the alarm recovery process in the pre-processing in advance. Thereby, it is possible to execute the process recipe after confirming that the current value of the maintenance item is lower than the threshold value of performing the maintenance process. For example, even when the current value of the maintenance item exceeds the threshold value of performing the maintenance process, it is possible to stabilize the result of the substrate processing since the process recipe is executed after the current value is set to zero (0) by performing the maintenance process.

(d) According to the present embodiment, even when the process recipe is executed continuously twice or more and the apparatus (for example, the controller 121 of the substrate processing apparatus 10) recognizes (or determines) that the scheduled maintenance threshold is reached during the execution of the first process recipe described above and the maintenance process should be performed, it is possible to execute the maintenance process at the first step of the pre-processing of the second process recipe described above. Therefore, it is possible to reset the current value of the maintenance item of the target object to zero (0) in the first step of the pre-processing of the second process recipe described above before executing the second process recipe described above.

(e) According to the present embodiment, even when the process recipe is executed continuously twice or more and the apparatus (for example, the controller 121 of the substrate processing apparatus 10) recognizes (or determines) that the scheduled maintenance threshold is reached during the execution of the first process recipe described above and the maintenance process should be performed, it is possible to execute the second process recipe described above after resetting the current value of the maintenance item of the target object to zero (0) by executing the maintenance recipe in the first step of the pre-processing of the second process recipe described above. Therefore, it is possible to improve the reliability of the result of the substrate processing.

(f) According to the present embodiment, by executing the N₂ purge recipe in the first step of the sub recipe, it is possible to blow off the particles serving as a particle source stagnant in the dead space of the seal cover (that is, the seal cap 219) with the large flow of the inert gas.

### Other Embodiments

While the technique is described in detail by way of the above-described embodiment, the above-described technique is not limited thereto. The above-described technique may be modified in various ways without departing from the scope thereof. For example, according to the present embodiment, in order not to affect the result of the substrate processing in the main processing (the boat loading step, the processing step and the boat unloading step), the maintenance recipe is included in the first step of the pre-processing so as to prepare the environment in the process furnace 202 at the start of the main processing (at the start of the process recipe). This is to be expected because the first step of the pre-processing is the step farthest from the first step of the main processing. However, for example, if it is anticipated that the result of the main processing (the boat loading step, the processing step and the boat unloading step) will not be affected as long as the time duration from the end of the maintenance recipe to the start of the first step of the main processing is set to be equal to or longer than a predetermined time, the maintenance recipe can be omitted from the first step of the pre-processing by securing the predetermined time between the end of the maintenance recipe to the start of the first step of the main processing.

While the above-described embodiment is described by way of an example in which the controller 121 is embodied by a dedicated computer, the controller 121 is not limited to the dedicated computer. For example, the controller 121 may be embodied by a general computer. For example, the controller 121 may be embodied by preparing an external memory storing the above-described program and installing the program stored in the external memory into the general computer. For example, the external memory may include a semiconductor memory such as a USB memory. The means for providing the program to the computer is not limited to the external memory. The program may be supplied to the computer using communication means such as the Internet and a dedicated line without using the external memory. The memory 128 or the external memory may be embodied by a non-transitory computer readable recording medium. The memory 128 and the external memory may be individually or collectively referred to as the recording medium. That is, in the present specification, the term “recording medium” may refer to only the memory 128, only the external memory or both of the memory 128 and the external memory.

Further, while the above-described embodiment is described by way of an example in which the substrate processing apparatus 10 is configured as a semiconductor manufacturing apparatus of manufacturing the semiconductor device, the above-described technique is not limited thereto. The above-described technique may be applied to an LCD (Liquid Crystal Display) manufacturing apparatus of processing a glass substrate. In addition, the above-described technique may also be applied to other substrate processing apparatuses such as an exposure apparatus, a photolithography apparatus, a coating apparatus and a processing apparatus using plasma.

According to some embodiments in the present disclosure, conditions in the process furnace can be made equal before and after the film-forming process, and a film-forming stability can be achieved.

What is claimed is:

1. A method of manufacturing a semiconductor device, comprising:
pre-processing of preparing a process environment in a process furnace of a substrate processing apparatus;
film-forming by processing a substrate; and
post-processing,
wherein the pre-processing comprises (a1) determining whether to execute a maintenance recipe for a target object in the substrate processing apparatus, wherein (a1) is performed first in the pre-processing.

2. The method of claim 1, wherein (a1) comprises executing a sub recipe, and
the sub recipe comprises (b1) determining whether to execute the maintenance recipe, wherein (b1) is performed first in the sub recipe.

3. The method of claim 2, wherein (b1) comprises:
(c1) checking execution settings for the maintenance recipe; and
(c2) comparing a current value of a pre-set maintenance item with a threshold value.

4. The method of claim 3, wherein, when the current value of the pre-set maintenance item reaches the threshold value, the maintenance recipe is executed and a next step of (b1) is performed.

5. The method of claim 4, wherein the current value of the pre-set maintenance item is reset to zero (0) when the maintenance recipe is completed.

6. The method of claim 3, wherein the maintenance item comprises at least one selected from a group consisting of: the number of times that the main processing is performed; the usage time of the target object; an amount of time that the target object has spent in the substrate processing apparatus; an accumulative thickness of a film registered in advance; the number of usable substrates remaining; a standby time; the number of times that the maintenance process is performed; the number of times that dummy wafers are used; and an accumulative thickness of the film formed on the dummy wafers.

7. The method of claim 2, wherein the sub recipe further comprises (b2) transferring the substrate, and (b2) is performed after (b1) is performed.

8. The method of claim 7, wherein the sub recipe is terminated after (b2) is performed so as to proceed to a next step of (a1).

9. The method of claim 2, wherein the sub recipe is forcibly terminated so as to proceed to the post-processing when the maintenance recipe is not normally terminated.

10. The method of claim 1, wherein a sub recipe is executed if a predetermined maintenance process is set up in (a1), and
the pre-processing is performed without executing the sub recipe if the predetermined maintenance process is not set up in (a1).

11. The method of claim 10, wherein one is selected as the maintenance process from a group consisting of: no designation; notifying the alarm; suspending a next process when a current process is completed; starting the maintenance process after receiving a start instruction; starting the maintenance process automatically unless another process is being performed; and executing a predetermined alarm recipe.

12. The method of claim 11, wherein the sub recipe is executed if executing the predetermined alarm recipe is selected as the maintenance process.

13. The method of claim 1, wherein the pre-processing further comprises:
(a2) transferring the substrate into a substrate retainer; and
(a3) preparing a transfer environment in which the substrate retainer and the substrate are in standby below the process furnace.

14. The method of claim 1, wherein the maintenance recipe comprises at least one selected from a group consisting of a purge recipe, a warm-up recipe and a cleaning recipe.

15. The method of claim 14, wherein the purge recipe comprises:
(d1) supplying a purge gas while an inner pressure and an inner temperature of the process furnace are maintained at a predetermined pressure and a predetermined temperature, respectively.

16. The method of claim 15, wherein the purge recipe further comprises:
(d2) inserting a substrate retainer into the process furnace; and
(d3) transferring the substrate retainer out of the process furnace.

17. The method of claim 16, wherein the purge recipe further comprises:
(d4) cooling the substrate retainer.

18. The method of claim 1, wherein the target object comprises at least one selected from a group consisting of a pod, the substrate, a boat, a reaction tube and the substrate processing apparatus.

19. A non-transitory computer-readable recording medium storing a program related to a substrate processing apparatus comprising a memory and a controller, wherein the memory stores a file at least comprising: a main recipe comprising pre-processing of preparing a process environment in a process furnace, film-forming by processing a substrate, and a post-processing; and a maintenance recipe configured to maintain a target object in the substrate processing apparatus, and wherein the controller is configured to execute the main recipe and the maintenance recipe through a recipe execution controller,
wherein the program causes, by a computer, the substrate processing apparatus to perform:
executing the maintenance recipe through the recipe execution controller first in the pre-processing.

20. A substrate processing apparatus comprising:
a memory configured to store a file at least comprising:
a main recipe comprising:
pre-processing of preparing a process environment in a process furnace;
film-forming by processing a substrate; and
post-processing; and
a maintenance recipe configured to maintain a target object in the substrate processing apparatus; and
a controller configured to be capable of causing a recipe execution controller to execute the main recipe and the maintenance recipe,
wherein the recipe execution controller is configured to be capable of executing the maintenance recipe in the first step of the pre-processing.
